(19) United States
(12) Patent Application Publication
(10) Pub. No.: US 2012/0288996 A1
(43) Pub. Date: Nov. 15, 2012

(54) METHODS AND APPARATUS FOR APPLYING AN ADHESIVE TO A CIRCUIT BOARD

(76) Inventors: Seah S. Too, Redmond, WA (US); Kiat Heng Tee, Lepas (MY)

(21) Appl. No.: 13/106,231

(22) Filed: May 12, 2011

(51) Int. Cl. H01L 21/50; H01L 21/58

(52) U.S. Cl. 438/108; 29/740; 257/E21.499

(57) ABSTRACT

Methods and apparatus for curing an adhesive on a circuit board are disclosed. In one aspect, a method of manufacturing is provided that includes isolating a first portion of a surface of a circuit board from a second portion of the surface with a flexible gasket. An adhesive is applied to the first portion of the surface. The adhesive is thermally cured. The flexible gasket prevents constituents outgassed from the adhesive from contaminating the second portion of the surface.

### BACKGROUND OF THE INVENTION

1. Field of the Invention

This invention relates generally to semiconductor processing, and more particularly to methods and apparatus for curing stiffener ring adhesives.

2. Description of the Related Art

Many current integrated circuits are formed as multiple semiconductor chips on a common silicon wafer. After the basic process steps to form the circuits on the semiconductor chips are complete, the individual semiconductor chips are cut or singulated from the wafer. The singulated semiconductor chips are then usually mounted to structures, such as circuit boards, or packaged in some form of enclosure.

One frequently-used package consists of a substrate upon which a semiconductor chip is mounted. The upper surface of the substrate includes conductive pads. The semiconductor chip is manufactured with a plurality of bump pads. A collection of solder joints are provided between the bump pads of the semiconductor chip and the corresponding conductive pads of the package substrate to establish ohmic contact. After the semiconductor chip is seated on the substrate, a reflow process is performed to enable the solder bumps of the semiconductor chip to metallurgically link to the solder pads of the substrate.

For conventional semiconductor chip packages, there may be significant differences in the coefficients of thermal expansion (CTE) of the semiconductor chip, the package substrate and the solder joints. Large differences in CTE coupled with thermal stresses associated with testing and operation can impose significant strains on solder joints. To lessen the effects of differential CTE, an underfill material is often deposited between the semiconductor chip and the package substrate to act as a material that inhibits damage to the solder bumps due to mismatches in CTE.

One conventional type of substrate consists of a core laminated between upper and lower build-up layers. The core itself usually consists of four layers of glass-filled epoxy. The build-up layers, which may number four or more on opposite sides of the core, are formed from some type of resin. Various metallization structures are interspersed in the core and build-up layers in order to provide electrical pathways between pins or pads on the lowermost layer of the substrate and pads that bond with the chip solder bumps.

The core provides a certain stiffness to the substrate. Even with that provided stiffness, conventional substrates still tend to warp due to mismatches in the CTE's for the semiconductor chip, the underfill and the package substrate.

One conventional technique for addressing package substrate warpage involves the use of a stiffener ring on the semiconductor chip side of the package substrate. A typical conventional stiffener ring includes a central opening to accommodate the semiconductor chip while leaving a gap. The gap is used to dispense the aforementioned underfill. Underfill is conventionally dispensed in the gap as a dot or a line. After dispensing, capillary action draws the underfill into the space between the semiconductor chip and the package substrate.

Some conventional stiffener rings are made of metallic materials, while others are formed from plastics. Whether metal or plastic, an adhesive is typically used to secure the stiffener ring to the package substrate. The adhesive typically requires some form of thermal cure prior to chip attach to harden and bond the opposing surfaces. The heating may cause the adhesive to outgass vapors and materials that either condense or settle on the surface of the package substrate. These contaminants may prevent the later-applied underfill from uniformly flowing and bonding. Voids in the underfill can lead to thermal and mechanical issues.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes isolating a first portion of a surface of a circuit board from a second portion of the surface with a flexible gasket. An adhesive is applied to the first portion of the surface. The adhesive is thermally cured. The flexible gasket prevents constituents outgassed from the adhesive from contaminating the second portion of the surface.

In accordance with another aspect of an embodiment of the present invention, a method of manufacturing is provided that includes preheating an adhesive to outgass constituents, applying the adhesive to a surface of a circuit board, and thermally curing the adhesive.

In accordance with another aspect of an embodiment of the present invention, an apparatus is provided that includes a first member that has a first flexible gasket to engage a surface of a circuit board to isolate a first portion of the surface from a second portion of the surface.

In accordance with another aspect of an embodiment of the present invention, an apparatus is provided that includes a circuit board that has a surface with a first portion and a second portion and an adhesive coupled to the second portion. A member has a flexible gasket to engage the surface and isolate the first portion from the adhesive.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a circuit board carrier;

FIG. 2 is a sectional view of FIG. 1 taken at section 2-2;

FIG. 3 is a portion of FIG. 2 shown at greater magnification;

FIG. 4 is a pictorial view of the body of the exemplary circuit board carrier;

FIG. 5 is a pictorial view of an exemplary member for isolating portions of circuit boards;

FIG. 6 is a pictorial view of another exemplary member for aligning circuit boards in the body;

FIG. 7 is sectional view of the exemplary circuit board carrier with the isolating member exploded and a furnace shown schematically;

FIG. 8 is schematic view of an exemplary circuit board, stiffener ring and adhesive undergoing plasma cleaning and precuring;

FIG. 9 is a pictorial view of an exemplary circuit board undergoing flip-chip attach and underfill application;

FIG. 10 is a flow chart of an exemplary stiffener ring attach process; and

FIG. 11 is a flow chart of an alternate exemplary stiffener ring attach process.

### DETAILED DESCRIPTION OF SPECIFIC EMBODIMENTS

Various embodiments of methods and apparatus for curing an adhesive on a circuit board are disclosed. One example includes a member that has a first flexible gasket to engage a surface of a circuit board to isolate a first portion of the surface from a second portion of the surface. With the member in place, the adhesive may be thermally cured. The member and flexible gasket prevent outgassed contaminants from the adhesive from settling on sensitive areas of the circuit board, such as a bump array slated for eventual underfill application. Additional details will now be described

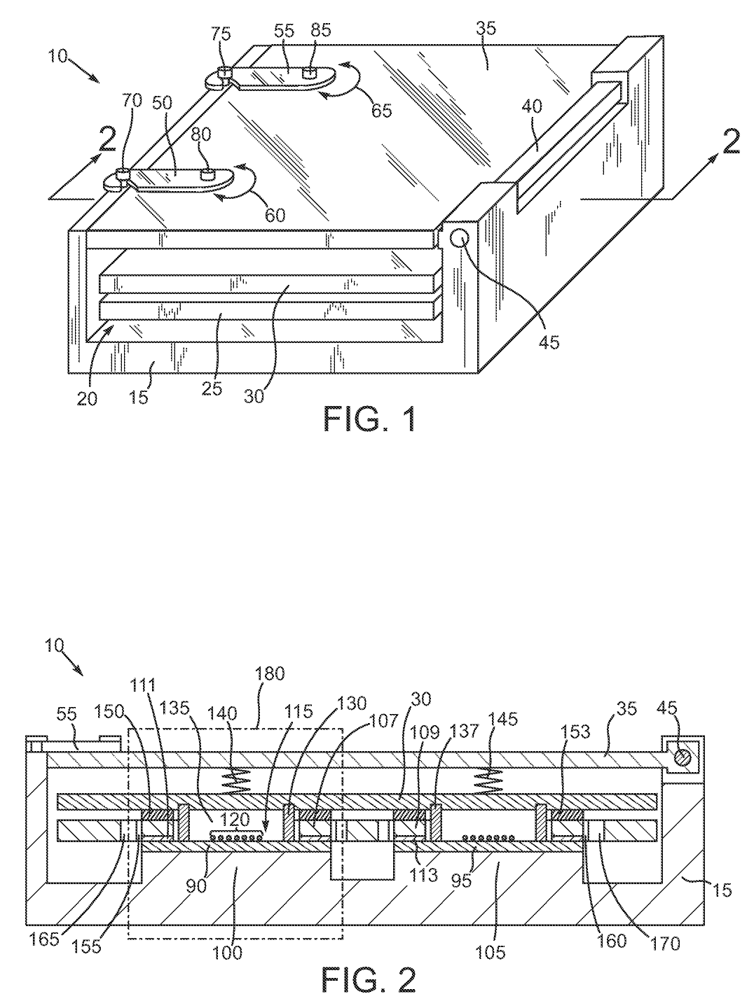

In the drawings described below, reference numerals are generally repeated where identical elements appear in more than one figure. Turning now to the drawings, and in particular to FIG. 1 is a pictorial view of an exemplary embodiment of a circuit board carrier or bookcase 10. The bookcase 10 is designed to hold one or more circuit boards (not visible) during various processing steps, such as component attach, heating, application of various films and materials etc. The bookcase 10 may include a generally U-shaped body 15 that has an interior space 20 for holding one or more members or plates 25 and 30. The structure and function of the plates 25 and 30 will be described in more detail below. The bookcase 10 may include a lid 35 that is pivotably connected to the body 15 by way of a hinge 40 and pin 45. The lid 35 may be secured in a closed position as shown in FIG. 1 by way of spaced-apart latches 50 and 55. The latches 50 and 55 are pivotable as indicated by the arrows 60 and 65 and operable to engage respective pins 70 and 75 that are coupled to the body 15. The latches 50 and 55 may be pivotably connected to the lid 35 by way of respective pins 80 and 85. As described more fully below, the lid 35 is operable to compress the plate 30 against the plate 25 to cordon off select portions of the circuit boards (not visible). However, it should be understood that a variety of different types of mechanisms other than the lid 35 and the body 15 may be used to provide compression of the plate 30 against the plate 25. Furthermore, the skilled artisan will appreciate that a variety of mechanisms may be used to secure the lid 35 in place, such as latches, friction fits, magnets or virtually any other type of fastening mechanism. The components of the bookcase 10 as well as the racks 25 and 30 are designed to hold relatively sensitive components, such as circuit boards, during various processing steps. Accordingly, it is desirable for the components of the bookcase 10 and the racks 25 and 30 to be composed of relatively inert materials, such as stainless steel, aluminum, or other materials resistant to corrosion and/or contamination.

Additional details of the bookcase 10 and the racks 25 and 30 may be understood by referring now to FIG. 2, which is a sectional view of FIG. 1 taken at section 2-2. Due to the location of section 2-2, the latch 55 of the lid 35 is visible but the other latch 50 is not. As noted briefly above, the body 15 is designed to hold the racks 25 and 30 as well as one or more circuit boards. In this sectional view, two exemplary circuit boards 90 and 95 are visible. To establish substantially planar support surfaces for the circuit boards 90 and 95, the body 15 may be provided with upwardly projecting platforms or plateaus 100 and 105. The use of plateaus 100 and 105 provides for easier physical access to the circuit boards 90 and 95, but a purely planar surface supporting all of the circuit boards 90 and 95 could be used as well.

The circuit boards 90 and 95 can number other than two and take on a variety of configurations. Examples include a semiconductor chip package substrate, a circuit card, or virtually any other type of printed circuit board. Although a monolithic structure could be used for the circuit boards 90 and 95, a more typical configuration will utilize a buildup design. In this regard, the circuit boards 90 and 95 may consist of a central core upon which one or more buildup layers are formed and below which an additional one or more buildup layers are formed. The core itself may consist of a stack of one or more layers. If implemented as a semiconductor chip package substrate, the number of layers in the circuit boards 90 and 95 can vary from four to sixteen or more, although less than four may be used. Coreless designs may be used as well. The layers of the circuit board 90 and 95 may consist of an insulating material, such as various well-known epoxies, interspersed with metal interconnects. A multi-layer configuration other than buildup could be used. Optionally, the circuit boards 90 and 95 may be composed of well-known ceramics or other materials suitable for package substrates or other printed circuit boards. The circuit boards 90 and 95 are provided with a number of conductor traces and vias and other structures (not visible) in order to facilitate movement of power, ground and signals.

In this illustrative embodiment, the circuit boards 90 and 95 includes respective stiffener rings 107 and 109 secured by respective adhesive beads 111 and 113. The following description of the circuit board 90 will be illustrative of the other circuit board 95 and any others in the disclosed embodiments. The circuit board 90 includes a central area 115 that may be provided with a bump array 120 and is circumscribed by the stiffener ring 107. The bump array 120 consists of plural solder structures that together with corresponding solder structures on a semiconductor chip (not visible) may be used to form a C4 bump array. The stiffener ring 107 may be composed of a variety of stiffener ring materials, such as stainless steel, copper, plastics or the like. The adhesive 111 may be a well-known thixotropic adhesive, an epoxy, another type of polymer. Regardless of exact composition, the adhesive bead 111 may exhibit outgassing during thermal cure. In order to prevent the outgassing from contaminating the central area 115 and particularly the bump array 120, the plate 30 is provided with a flexible gasket 130. Note that the backside wall 135 of the gasket 130 is visible. The gasket 130 provides a barrier against the intrusion of contaminants from outgassing or otherwise into the central area 115 and proximate the bump array 120. The gasket 130 may be composed of a variety of materials such as various fluoroelastomers, such as Viton, various rubbers such as nitrile, or like materials. Softness and relatively low levels of native outgassing are preferred characteristics. The gasket 130 may be secured to the plate 30 by interference fit as shown, or by adhesives or other fastening techniques or combinations thereof as desired. The plate 30 includes another gasket 130 like the gasket 125 to seal the circuit board 95.

The gasket 130 is brought into compressive engagement with the circuit board 90 by way of one or more springs 140 and 145 connected to the lid 35. Thus, when the lid 35 is pivoted about the pin 45 downward and latched, the springs 140 and 145 press the plate 30 and thus the gasket 130 against the circuit board 90. In addition, the plate 30 is provided with a downwardly-facing compliant secondary gaskets 150 and 153 that are designed to bear against the stiffener rings 107 and 109 to slightly compress the adhesive beads 111 and 115 during finishing thermal cures. The secondary gaskets 150 and 153 may be composed of a variety of materials, such as silicone, fluoroelastomers, rubbers or the like, and may be secured to the plate 30 by adhesives, interference fits or the like. The springs 140 and 145 may be coil springs as shown, leaf springs or virtually any other type of biasing members.

The plate 25 is designed as an alignment device that provides initial alignment of the circuit boards 90 and 95 after placement on the plateaus 100 and 105. To accommodate the circuit boards 90 and 95, the plate 25 includes corresponding openings 155 and 160. The openings 155 and 160 may include cutout extensions 165, 170 and two other cutouts that are not readily visible in FIG. 2 but will be shown in subsequent figures. The cutouts 165 and 170 are designed to enable ready access to the circuit boards 90 and 95 in order to facilitate movement or removal thereof.

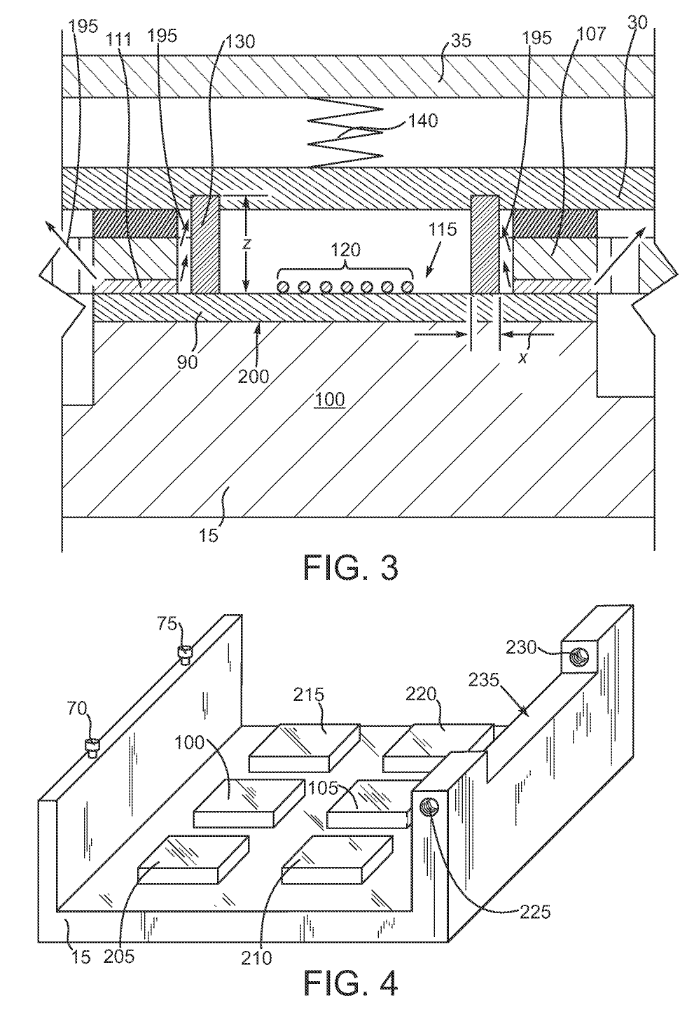

The portion of FIG. 2 circumscribed by the dot and dashed box 180 will be shown at greater magnification in FIG. 3. Attention is now turned to FIG. 3, which as just noted, is the portion of FIG. 2 circumscribed by the dot and dashed box 180 but shown at greater magnification. As noted above, when the gaskets 130 and 150 of the plate 30 are brought into engagement with the circuit board 90 and the stiffener frame 107 by compression applied from the lid 35 and the spring 140, the central area 115 of the circuit board 90 and the bump array 120 are sealed off from outgassing (represented by the arrows 195) from the adhesive bead 111. In this way, the thermal curing of the adhesive bead 111 may be accomplished without contaminating the central area 115. The uncompressed height z of the gasket 130 should be large enough to seal against the circuit board 90 while permitting the gasket to engage the stiffener ring 107. A post-compression height of about 0.8z may be suitable. An exemplary width x of the gasket 107 may be about 1.0 mm.

Still referring to FIG. 3, the circuit board 90 is not depicted with any type of input/output array on the underside 200 thereof. However, it should be understood that the circuit board 90 could be a ball grid array, a pin grid array, a land grid array or some other type of input/output device. Optionally, the circuit board 90 may not have an input/output system for the lower side 200 thereof.

Additional details of the body 15 may be understood by referring now to FIG. 4, which is a pictorial view with the lid 35 and the pin 45 shown in FIGS. 1 and 2 removed as well as without the plates 25 and 30 or any of the circuit boards positioned thereon. The plateaus 100 and 105 visible in FIG. 2 are shown pictorially as well as four other plateaus 205, 210, 215 and 220. To hold the pin 45 shown in FIGS. 1 and 2, the body 15 is provided bores 225 and 230. To accommodate the hinge 40 shown in FIG. 1, portions of the body 15 that include the bores 225 and 230 are separated by a cutout 235. The latch pins 70 and 75 on the opposite side of the cutout 235 are visible. It should be understood that the disclosed embodiment includes six plateaus 100, 105, 205, 210, 215 and 220. However, any number of plateaus may be provided depending upon the size of both the body 15 and the circuit boards that must be supported thereon.

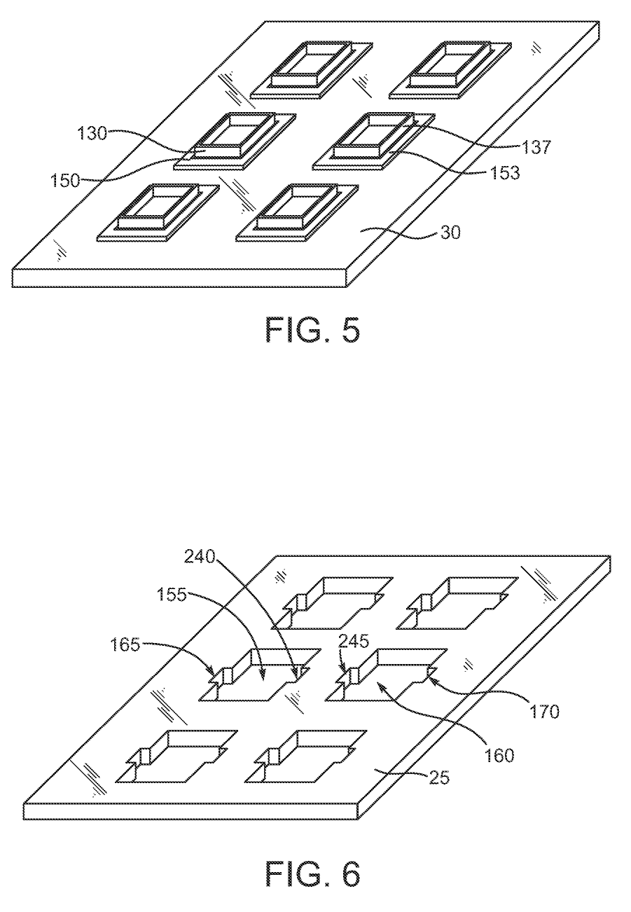

Additional details of the plate 30 may be understood by referring now to FIG. 5, which is a pictorial view of the exemplary plate 30 shown flipped over from the orientation depicted in FIGS. 1 and 2. Accordingly, the gaskets 130, 137, 150 and 153 are visible as well as four other similar or identical gasket sets that are not separately labeled. In this way, six circuit boards may be simultaneously sealed to prevent contamination during adhesive cure. Here, the gaskets 130, 137, 150 and 153 and the others not separately labeled may have a generally rectangular footprint that matches a common rectangular footprint for many circuit boards. However, the skilled artisan will appreciate that the gaskets 130, 137, 150 and 153 may have other than a rectangular footprint and come in any number as desired.

Additional details of the alignment plate 25 may be understood by referring now to FIG. 6, which is a pictorial view. Here, the openings 155 and 160 shown in FIG. 2 are visible along with four other openings to accommodate other circuit boards but which are not separately labeled. As noted above in conjunction with FIG. 2, the opening 155 includes an opening extension 165 and further includes an opposite opening extension 240, which was not separately labeled in FIG. 2. The opening 160 similarly includes the previously identified opening extension 170 as well as an oppositely positioned open extension 245. Again, the extensions 165, 240, 170 and 245 are designed to facilitate tool or even thumbnail access to the stiffener rings of given circuit board. The openings 155, 160 and the other unlabeled openings may be formed by machining, punching, casting or virtually any other material fashioning techniques.

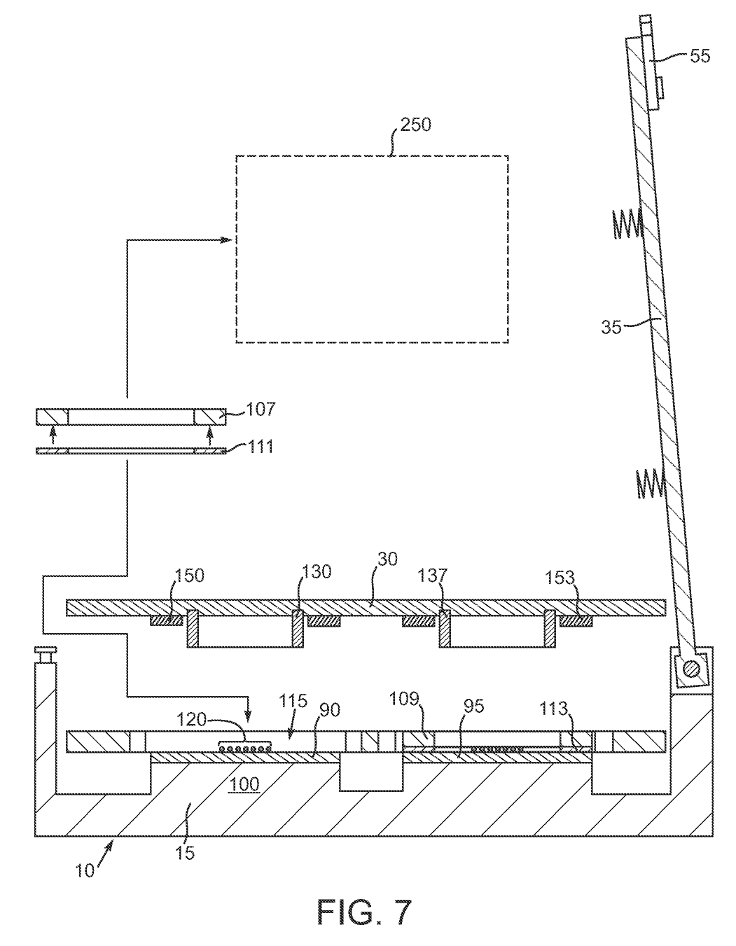

An exemplary method for attaching a stiffener frame to a circuit board may be understood by referring now to FIG. 7, which is a sectional view of the bookcase 10 with the lid 35 flipped open and the plate 30 exploded vertically from the body 15. Initially, the circuit board 90 is positioned on the plateau 100 with or without the benefit of the alignment plate 25. Before, after or simultaneously, the adhesive bead 111 may be applied to the stiffener frame 107 by dispensing, brushing, spraying or the like. The stiffener frame 107 and the adhesive bead 111 may then be heated in a suitable furnace 250 to precure the adhesive 111. The purpose of the precure is to compel a preliminary outgassing of vapors and other constituents from the adhesive bead 111 so that the majority of the outgassing occurs prior to positioning proximate the central region 115 and bump array 120 of the circuit board 90. Suitable temperatures and times for the precure will depend on the compositions of the adhesive 111 and the stiffener ring 107. Fast curing adhesives may require as little as about 2.0 minutes at 100° C., however, a precure time of about 3 to 10 minutes at 100° C. will be more typical. Subsequent to the precure, the stiffener frame 107 and adhesive bead 111 may be removed from the furnace 250 and positioned on the circuit board 90. Note that the stiffener ring 109 and adhesive 113 are shown following precure and stiffener ring attach. The plate 30 may be dropped down seated on the circuit boards 90 and 95 and the gaskets 130 and 137 brought into engagement with the circuit boards 90 and 95, and the gaskets 150 and 153 into engagement with the stiffener rings 107 and 109 via pivoting movement of the lid 35 and engagement of the latch 55 as described above. With the plate 30 in compression, a final thermal cure of the adhesives 111 and 113 may be provided by positioning the entire bookcase 10 in a suitable furnace, such as the furnace 250, and heated to about 125° C. for about 1.5 hours to final cure. Again the temperature and time will depend on the adhesive used. As described elsewhere herein, the gaskets 130 and 137 prevent the unwanted migration of outgassing constituents from the adhesive beads 111 and 113.

An alternate exemplary method that renders optional the use of a gasket-fitted plate may be understood by referring now to FIG. 8. FIG. 8 depicts the stiffener frame 107, the adhesive bead 111 and the circuit board 90 in section. In this illustrative method, the adhesive bead 111 may be initially secured to the stiffener frame 107 and then subjected to a precure in the furnace 250 as described above. Thereafter, the stiffener frame 107 may be secured to the circuit board 90 and a final cure performed. This final thermal cure need not use a gasket-fitted plate described above. Following the final thermal cure, the circuit board 90 may be placed in a plasma cleaning chamber 255 and subjected to a plasma cleaning process using argon, oxygen or other ambients to remove contaminants from the central region 115.

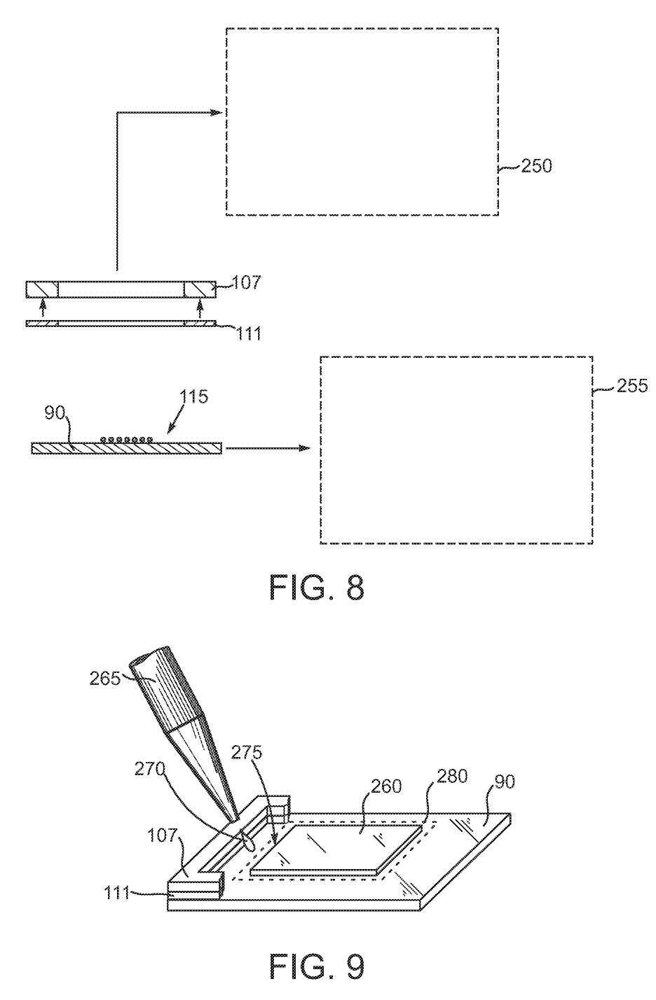

Following the attachment of a stiffener frame to a given circuit board using either of the illustrative techniques disclosed herein, a semiconductor chip may be flip-chip attached thereto and an underfill material applied. Suitable types of application processes for the underfill material will depend on, among other things, the type of stiffener frame attachment process used. With this backdrop, attention is now turned to FIG. 9, which is a pictorial view of an exemplary semiconductor chip 260 flip-chip mounted to the circuit board 90. The stiffener ring 107 and the adhesive 111 are shown partially cut away. The processes disclosed herein are not dependent on the functionality of the semiconductor chip 260. Thus, the semiconductor chip 260 may be any of a myriad of different types of circuit devices used in electronics, such as, for example, microprocessors, graphics processors, combined microprocessor/graphics processors, application specific integrated circuits, memory devices, active optical devices, such as lasers, or the like, and may be single or multi-core or even stacked laterally with additional dice. Furthermore, the semiconductor chip 260 could be configured as an interposer with or without some logic circuits. Thus the term “chip” includes an interposer and vice versa. The semiconductor chip 260 may be constructed of bulk semiconductor, such as silicon or germanium, or semiconductor on insulator materials, such as silicon-on-insulator materials, or even other types of materials, even insulating materials such as silicon dioxide, tetra-ethyl-ortho-silicate or others. It should be understood that multiple chips 260 could be mounted. A suitable applicator 265 may be used to dispense underfill 270 on the circuit board 90 proximate the semiconductor chip 260. The application may be with or without a seal pass. If the underfill 270 is dispensed without a seal pass, then the underfill 270 may be applied proximate, for example, one edge 275 of the semiconductor chip 260 and capillary action thereafter used to move the underfill 27 throughout the entire gap between the semiconductor chip 260 and the circuit board 90. If a seal pass is used, then the underfill 270 may be applied not only at the edge 275 but also around the perimeter 280 of the semiconductor chip 260. The usage of a seal pass around the perimeter 280 requires additional time and material, but may be appropriate in circumstances where, for example, the plate 30 with the gasket seals 130 and 137 (see FIGS. 2 and 7) is not used during the final thermal curing of the stiffener ring adhesive 111. Conversely, the usage of the plate with the sealing gaskets 130 and 151 may leave the central region 110 sufficiently clear of contaminants so that the underfill 270 may be dispensed without a seal pass. The underfill 270 may be composed of well-known epoxy materials, such as epoxy resin with or without silica fillers and phenol resins or the like. Two examples are types 8437-2 and 2BD available from Namics.

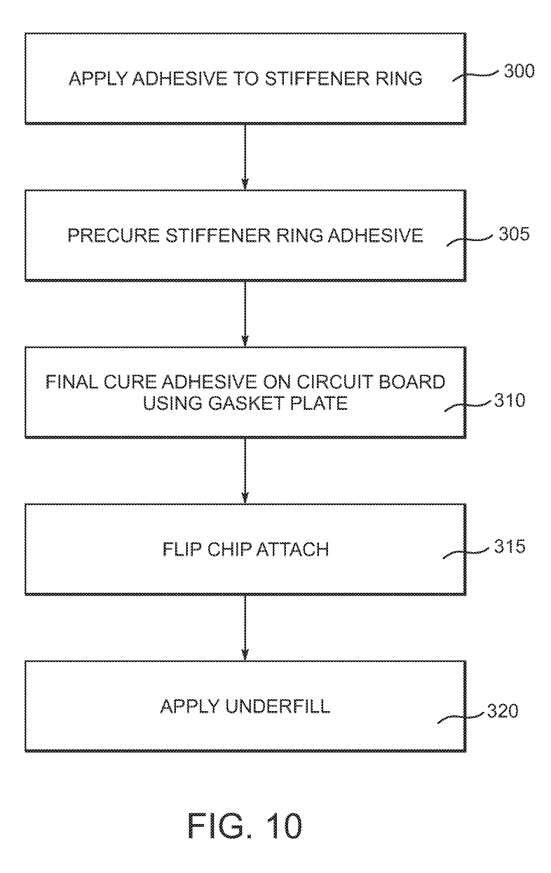

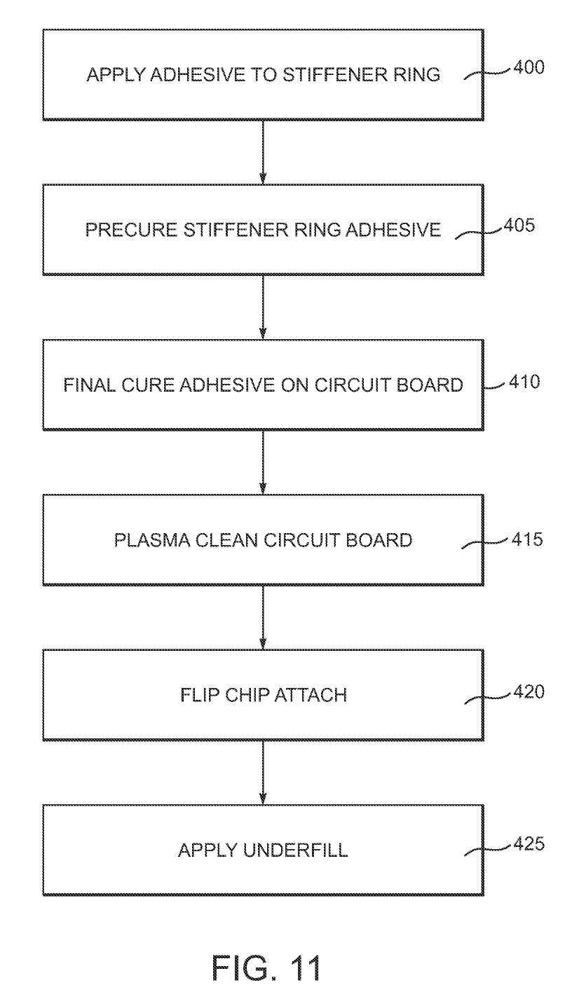

Flow charts for two exemplary methods are depicted in FIGS. 10 and 11. Referring first to FIG. 10, at step 300 an adhesive may be applied to a stiffener ring, at step 305 the stiffener ring adhesive may undergo a precure as described elsewhere herein, at step 310 the adhesive may be subject to a final cure on a circuit board using the aforementioned gasket-fitted plate, at step 315 a semiconductor chip may be flip-chip attached to the circuit board, and at step 320 an underfill may be applied without a seal pass if desired. An alternate process flow is depicted pictorially in FIG. 11. In this illustrative method, at step 400 an adhesive is applied to a stiffener ring, at step 405 the stiffener ring adhesive is subjected to a precure, at step 410 a final thermal cure is performed on the adhesive on a circuit board, at step 415 the circuit board is subjected to a plasma treatment for contaminant cleansing, at step 420 a semiconductor chip may flip-chip attached to the circuit board, and at step 425 an underfill material may be dispensed preferentially using a seal pass.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
isolating a first portion of a surface of a circuit board from a second portion of the surface with a flexible gasket;
applying an adhesive to the first portion of the surface; and
thermally curing the adhesive, the flexible gasket preventing constituents outgassed from the adhesive from contaminating the second portion of the surface.

2. The method of claim 1, comprising engaging the surface of the circuit board with the flexible gasket to isolate the first portion after application of the adhesive.

3. The method of claim 1, wherein the circuit board comprises a semiconductor chip package substrate.

4. The method of claim 1, wherein the second portion comprises a bump array.

5. The method of claim 1, comprising flip-mounting a semiconductor chip to the surface and placing an underfill between the semiconductor chip and the circuit board.

6. The method of claim 1, wherein a stiffener ring is coupled to the adhesive.

7. The method of claim 1, comprising preheating the adhesive to outgass constituents prior to isolating the second portion.

8. A method of manufacturing, comprising:
preheating an adhesive to outgass constituents;
applying the adhesive to the surface of a circuit board; and
thermally curing the adhesive.

9. The method of claim 8, wherein the circuit board comprises a semiconductor chip package substrate.

10. The method of claim 8, comprising flip-mounting a semiconductor chip to the surface and placing an underfill between the semiconductor chip and the circuit board.

11. The method of claim 8, wherein a stiffener ring is coupled to the adhesive.

12. An apparatus, comprising:
a first member having a first flexible gasket to engage a surface of a circuit board to isolate a first portion of the surface from a second portion of the surface.

13. The apparatus of claim 12, wherein the first member comprises a second flexible gasket adapted to engage a stiffener ring of the circuit board.

14. The apparatus of claim 12, wherein the first member comprises a plate.

15. The apparatus of claim 12, comprising a body having a surface to support the circuit board when the first flexible gasket is engaged with the surface.

16. The apparatus of claim 15, comprising a second member operable to bias the first member against the circuit board.

17. The apparatus of claim 16, wherein the second member comprises a lid pivotally coupled to the body.

18. The apparatus of claim of claim 11, wherein the body comprises a plateau to support the circuit board.

19. The apparatus of claim 15, comprising a third member having an opening sized to accommodate the circuit board, the third member being operable to provide lateral alignment of the circuit board on the support surface.

20. An apparatus, comprising:
a circuit board having a surface with a first portion and a second portion and an adhesive coupled to the second portion; and
a member having a flexible gasket to engage the surface and isolate the first portion from the adhesive.

21. The apparatus of claim 20, wherein the circuit board comprises a stiffener ring coupled to the adhesive, the member including a second flexible gasket adapted to engage the stiffener ring.
